(19) United States
(12) Patent Application Publication
(10) Pub. No.: US 2025/0055455 A1
(43) Pub. Date: Feb. 13, 2025

(54) AN ADAPTIVE BODY BIASING SYSTEM FOR SILICON ON INSULATOR SEMICONDUCTOR DEVICES AND A PRODUCTION TEST METHOD FOR TESTING SINGLE OR MULTIPLE ADAPTIVE BODY BIAS GENERATORS

(71) Applicant: RACYICS GMBH, Dresden (DE)

(72) Inventors: Alexander OEFELEIN, Dresden (DE); Sebastian HÖPPNER, Dresden (DE)

(73) Assignee: RACYICS GMBH, Dresden (DE)

(21) Appl. No.: 18/720,367

(22) PCT Filed: Dec. 1, 2022
(86) PCT No.: PCT/EP2022/084015

§ 371 Date: Jun. 14, 2024

(30) Foreign Application Priority Data
Dec. 17, 2021 (EP) 21215394.4

(51) Int. Cl. H03K 17/693; G01R 31/26; G01R 31/27

(52) U.S. Cl. CPC H03K 17/693; G01R 31/2644; G01R 31/275; H03K 2217/0018; H03K 2217/0054

(57) ABSTRACT

An adaptive body biasing system for silicon on insulator semiconductor devices includes
at least one biased logic domain;
at least one adaptive body bias generator for generating variable bias voltage; at least one test pad for accessing the generated bias voltage generated by the at least one adaptive body bias generator; and at least one bias switch cell connecting the at least one adaptive body bias generator to the at least one test pad. The at least one bias switch cell is in high-resistive off state during normal operation of the semiconductor device and can be switched to low-resistive on state during test operation. The at least one adaptive body bias generator is connected to the at least one biased logic domain.

The invention is in the field of adaptive body biasing (ABB) for silicon on insulator (SOI) technologies, particularly for fully depleted silicon on insulator (FDSOI), where bias voltages are adaptively generated by means of ABB generator circuits.

### BACKGROUND ART

An overview of the Silicon-on-Insulator (SOI) CMOS technologies is exemplary published in R. Carter et al., “22 nm FDSOI technology for emerging mobile. Internet-of-Things, and RF applications,” 2016 IEEE International Electron Devices Meeting (IEDM), San Francisco, CA, 2016, pp 2.2.1-2.2.4. doi: 10.1109/IEDM.2016.7838029. These technologies allow the adaptation of the threshold voltage of transistors by adjusting the body bias (back-gate) voltage as it is disclosed in G. de Streel and D. Bol, “Impact of back gate biasing schemes on energy and robustness of ULV logic in 28 nm UTBB FDSOI technology,” in Proc. IEEE Int. Symp. Low Power Electron. Design (ISLPED), September 2013, pp. 255-260.

The adaptation of the body bias voltage can be done during operation of the circuit in order to compensate variations in the fabrication process (P), of the supply voltage (V) and of the temperature (T) in order to achieve a defined delay time and/or leakage current consumption. The adaptation of the body bias threshold voltage is necessary to adjust an adaptive compromise between switching speed and leakage current consumption in order to be able to adapt the circuit or system with regard to the performance requirement.

Adaptive body biasing (ABB) for silicon on insulator (SOI) technologies are for example disclosed in EP 461 289 B1, U.S. Pat. Nos. 11,361,800, B2, 10,777,235 B2 and 11,183,224 B2.

Generally, the ABB generator generates two bias voltages for N-Well (VNW) and P-Well (VPW) bias nets. For test and measurement purposes, it is desired to have the VNW and VPW voltage signals accessible on test pads or package pads on the chip product. This requires the instantiation of dedicated bond or bump pads which require chip area and occupy IO pad resources in the package and on the system printed circuit board. Complex systems include multiple of ABB generator circuits targeted to bias separate bias domains, which would lead to high chip pin count to make the individual VNW and VPW voltages accessible for test and measurement. In other system configurations, multiple bias domains might be driven from a single ABB generator. The core bias domains might be required to directly be connected to a fixed voltage, e. g. ground for test and measurement purposes.

U.S. Pat. Nos. 5,703,522 A and 6,232,793 B1 propose a switched bias block with clocked embedded charge pump to connect N-Well and P-Well bias from two fixed bias supplies. This needs extra supply voltage levels. In U.S. Pat. Nos. 5,703,522A and 6,232,793B1 a transistor backgate is switched between two (or multiple) reference (bias) voltages. The structure consists of a transfer gate switch, and a common level shifter per selectable bias voltage. The level shifter supply voltage rails are assumed to be arbitrary, static, always-on and with a defined relation to the input control voltage level with regards to device safe-operating area in order to use common level shifter architectures.

U.S. Pat. No. 6,249,3458 discloses a negative bias switch cell which requires an extra negative supply voltage. The negative bias switch cell disclosed in U.S. Pat. No. 6,621,327 B2 is based on substrate voltage generation with capacitive DAC style loading of a voltage onto a capacitance. No charge pump is used for this. The resulting voltage is in only in the range between VDD and VSS. U.S. Pat. No. 6,621,325 B2 discloses the selection of well bias voltages for parts of the design by selection among multiple bias voltage sources. U.S. Pat. No. 7,859,062 B1 discloses that multiple body bias domains can be integrated on one chip but is does not disclose the switching between these domains during circuit operation. U.S. Pat. No. 7,978,001 B2 discloses selective substrate biasing of circuit parts of an integrated circuit based on the operational state of the circuit block.

In summary, the state-of-the art reports the connection and selection of one biased domain between multiple bias voltage generators and fixed bias supplies (U.S. Pat. No. 6,621,325 B2) and it does further report the switching of multiple biased circuit domains from one body bias generator (U.S. Pat. No. 7,859,062 B1).

What is not reported by the state of the art and therefore object of this invention is:
the problem of connecting multiple body bias generators to a test signal pad, without external additional supply voltages.
a well voltage bias switch cell without high and low (negative) supplies that allows to switch a bias supply by having a high-resistive off state and low resistive on state.

### SUMMARY OF THE INVENTION

According to the invention the object is solved by an adaptive body biasing system for silicon on insulator semiconductor devices, comprising:
at least one biased logic domain:
at least one adaptive body bias generator for generating variable bias voltages for N-Well and/or P-Well biased logic domains, wherein the at least one adaptive body bias generator is connected to the at least one biased logic domain:
at least one test pad for accessing the generated N-Well or P-Well bias voltage generated by the at least one adaptive body bias generator from outside of the semiconductor device; and
at least one bias switch cell connecting the at least one adaptive body bias generator to the at least one test pad and having a high-resistive off state and a low-resistive on state, wherein the at least one bias switch cell is in high-resistive off state during normal operation of the semiconductor device and can be switched to low-resistive on state during test operation.

Pursuant to the ABB system of the present invention, the adaptive body bias generator is connected to the biased logic domain, and the bias switch cell connects the body bias signal voltage to the at least one chip test pad. The body bias switch can be put to high-resistive off state and low resistive on-state. During normal circuit operation, the bias switch cell is in high-resistive off state. This has the benefit of the electrical isolation of the body bias nets from external chip pins. This improves aspects of functional safety. Additional ESD protection circuits can be connected to the test pads.

The invention particularly relates to:
Realization of a bias voltage switch that can switch VNW and/or VPW voltages within systems with adaptive body biasing, considering the wide positive and negative voltage ranges of VNW and/or VPW.
Connection of multiple ABB generator circuits to at least one test pad in a multiplexer scheme for reduced pad count to make all individual ABB generator instances testable and measurable.
The switchable connection of individual body bias domains on the chip to different ABB generator circuits.
The switchable connection of individual body bias domains between different ABB generator circuits and fixed bias voltages, e. g. ground potential.

In a variant of the invention, the adaptive body biasing system comprises multiple biased logic domains, multiple adaptive body bias generators and multiple bias switch cells, wherein each adaptive body bias generator is connected to a corresponding biased logic domain, and wherein each adaptive body bias generator is connected to the at least one test pad via a corresponding bias switch cell.

Thus, multiple adaptive body bias generators are connected to multiple biased logic domains, and multiple bias switch cells connect the multiple body bias signal voltages to the single chip test pad. During normal circuit operation, the bias switch cells are in high-resistive off state. Additional ESD protection circuits can be connected to the test pad. Each bias switch cell provides a configurable high-resistive (open) or low resistive (short) circuit connection between two nodes of arbitrary voltage, especially well bias voltages of high-positive (higher than supply) or low negative (lower than ground) voltage levels.

Pursuant to a variant of the invention, during test operation only one of the multiple bias switch cells is in low-resistive on state. Thus, only one adaptive body bias generator is connected to the chip test pad at a given time.

According to a variant of the invention, each bias switch cell comprises a clock signal input and/or enable signal input as a control signal and an input connection node for the at least one adaptive body bias generator and an output connection node for the at least one test pad. In low-resistive on state, the input connection node of the bias switch cell is electrically connected to the output connection node and in high-resistive off state the input connection node and the output connection node are electrically disconnected.

In a preferred variant of the invention, the control signal provided to each bias switch cell is independent and shares no reference node with the connection nodes.

In a further variant of the invention, the bias switch cell comprises a transfer gate device comprising a series connection of an input transfer switch and output transfer switch each having a high voltage rating for the respective input connection node and output connection node, which together realize a resistive bidirectional switch element between the connection nodes.

According to a preferred variant of the invention, the at least one bias switch cell comprises an input charge pump, an output charge pump, an input level shifter and an output level shifter for the respective input transfer switch and respective output transfer switch, wherein the input charge pump is connected to the input connection node and the input level shifter and the input level shifter is further connected to the input transfer switch and the output charge pump is connected to the output connection node and the output level shifter and the output level shifter is further connected to the output transfer switch. The input and output level shifter translates a dynamic control signal into an open or close information for the transfer gate device. Advantageously, the level shifter uses a connection node and a support voltage as reference nodes. The connection node is preferably the connection node of the charge pump of the bias switch cell.

Pursuant to an advantageous variant of the invention, the adaptive body biasing system comprises a first test pad for the N-Well bias voltage generated by the at least one adaptive body bias generator and a second test pad for the P-Well bias voltage generated by the at least one adaptive body bias generator. Particularly, the adaptive body biasing system comprises a single first test for the N-Well bias voltage generated by the at least one adaptive body bias generator and a single second test pad P-Well bias voltage generated by the at least one adaptive body bias generator.

In a variant of the invention, the at least one switch cell comprises a first signal path for the N-Well bias voltage generated by the at least one adaptive body bias generator and a second signal path for the P-Well bias voltage generated by the at least one adaptive body bias generator. Thus, the at least one bias switch cell can selectively and/or independently forward the N-Well bias voltage to the first test pad and the P-Well bias voltage to the second test pad.

According to a preferred variant of the invention, the first signal path comprises a first input connection node, a first output connection node, a first input charge pump, a first output charge pump, a first input transfer switch, a first output transfer switch, a first input level shifter and a first output level shifter and the second signal path comprises a second input connection node, a second output connection node, a second input charge pump, a second output charge pump, a second input transfer switch, a second output transfer switch, a second input level shifter and a second output level shifter.

Pursuant to a variant of the invention, the at least bias switch cell is bidirectional. Bidirectional in sense of the present invention means that signals can be transferred from any one connection node to any other connection node.

In a variant of the invention, the adaptive body biasing system further comprises a test mode, in which the adaptive body bias generator is in a non-functional mode and a bias voltage is externally applied to the adaptive body biasing system.

The invention further relates to a production test method for testing single or multiple adaptive body bias generators using an adaptive body biasing system according to any of claims 1 to 11, wherein a measurement of the generated bias voltage comprises the steps of:
enable one bias switch cell to connect a single adaptive body bias generator to the at least one test pad:
enable the selected adaptive body bias generator:
measure the bias voltage at the at least one test pad:
disable the bias switch cell; and
disable the adaptive body bias generator.

According to a variant of the invention, a measurement of the adaptive body bias generator output current comprises the steps of:
enable one bias switch cell to connect a single adaptive body bias generator to the at least one test pad:
enable the selected adaptive body bias generator:
apply a DC voltage source to the at least one test pad:
measure the current flowing through the at least one test pad:
disable the bias switch cell; and
disable the adaptive body bias generator.

Pursuant to a further variant of the invention, a testing and debugging comprises the steps of:
enable one or more bias switch cells to connect one or more adaptive body bias generators to the at least one test pad:
apply a bias voltage from external voltage source to the at least one test pad:
operate the logic in the biased logic domains in functional mode or in test mode:
disable the one or more bias switch cells; and
disable the one or more adaptive body bias generators.

### BRIEF DESCRIPTION OF THE DRAWING FIGURES

In the following, the invention will be further explained with respect to the embodiments shown in the figures. It shows:

FIG. 1 a block diagram of a first embodiment of an adaptive body bias system with a single ABB domain with bias switch cell for test-pad connection:

FIG. 2 a block diagram of a second embodiment of an adaptive body bias system with two ABB domains with bias switch cells for test pad connections,

FIG. 3 a circuit diagram of a first embodiment of a bidirectional bias switch cell for connecting a single input and output node:

FIG. 4 a block diagram of a third embodiment of an adaptive body bias system with a single ABB domain with bias switch cell for test-pad connection:

FIG. 5 a block diagram of a fourth embodiment of an adaptive body bias system with multiple ABB domains with bias switch cells for test-pad connection:

FIG. 6 a circuit diagram of a second embodiment of a bidirectional bias switch cell for connecting a single input and output node; and

FIG. 7 a block diagram of an adaptive body bias system under scan test with ABB generator scan chains and biased logic domain scan chains connected together.

### DETAILED DESCRIPTION

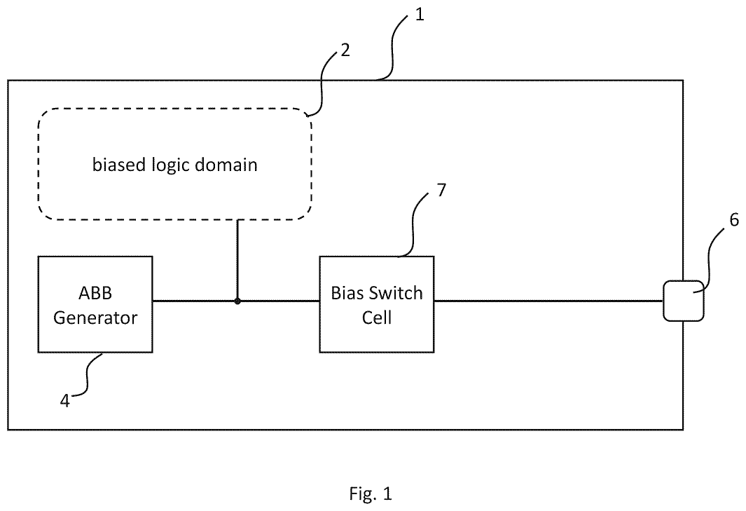

FIG. 1 shows a block diagram of a first embodiment of an adaptive body biasing system 1 for silicon on insulator semiconductor devices. The system 1 comprises one adaptive body biased logic domain 2, one adaptive body bias generator 4, one test pad 6 and one bias switch cell 7 for test pad 6 connection. The adaptive body bias generator 4 can generate one variable bias voltage for N-Well (VNW) or P-Well (VPW) biased logic domain. The adaptive body bias generator 4 is connected to the biased logic domain 2 and provides the N-Well or P-Well bias voltage to the biased logic domain 2.

The bias switch cell 7 connects the adaptive body bias generator 4 to the single pad 6 and has a high-resistive off state and a low-resistive on state. The bias switch cell 7 is in high-resistive off state during normal operation of the semiconductor device and can be switched to low-resistive on state during test operation. This has the benefit of the electrical isolation of the body bias logic domain 2 from external chip pin, particularly test pad 6, during normal operation. This improves aspects of functional safety. Additional ESD protection circuits can be connected to the test pad 6.

The single test pad 6 is for accessing the generated N-Well or P-Well bias voltage generated by the adaptive body bias generator 4 from outside of the semiconductor device.

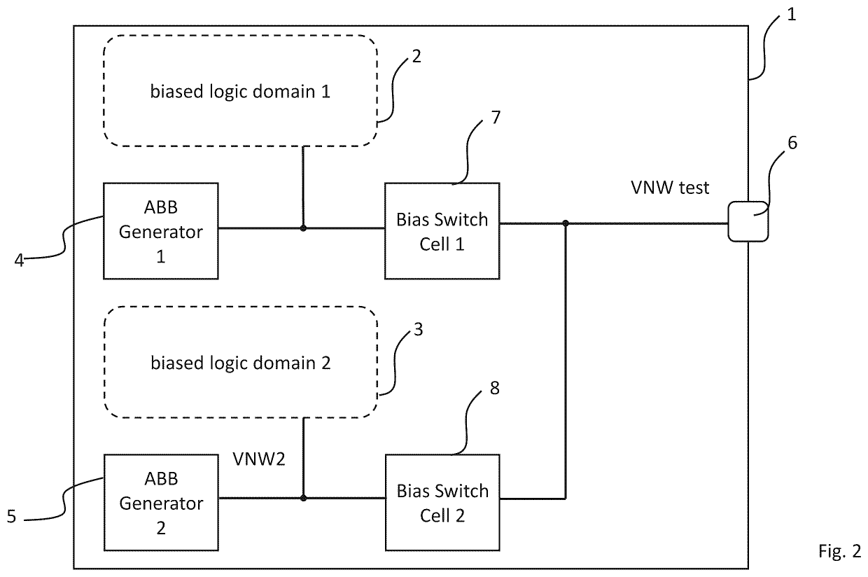

FIG. 2 shows a block diagram of a second embodiment of an adaptive body biasing system 1 for silicon on insulator semiconductor devices. The system 1 comprises a first adaptive body biased logic domain 2, a second body biased logic domain 3, a first adaptive body bias generator 4, a second adaptive body bias generator 5, a single test pad 6, a first bias switch cell 7 and a second bias switch cell 8 for test pad 6 connection. The first adaptive body bias generator 4 and the second adaptive body bias generator 5 can each generate a variable bias voltage for N-Well or P-Well biased logic domains. The first adaptive body bias generator 4 is connected to the first biased logic domain 2 and the second adaptive body bias generator 5 is connected to the second biased logic domain 3.

The first bias switch cell 7 connects the first adaptive body bias generator 4 to the single test pad 6 and the second bias switch cell 8 connects the second adaptive body bias generator 5 to the single test pad 6. The first bias switch cell 7 and the second bias switch cell 8 each have a high-resistive off state and a low-resistive on state. The bias switch cell 8 and the second bias switch cell 8 are in high-resistive off state during normal operation of the semiconductor device. The first bias switch cell 7 and the second bias switch cell 8 can be switched to low-resistive on state during test operation, wherein only one of the first and second bias switch cells 7, 8 is in low-resistive on state during test operation. This has the benefit of the electrical isolation of the first and second body bias logic domains 2, 3 from external chip pins, particularly test pad 6, during normal operation. This improves aspects of functional safety. Additional ESD protection circuits can be connected to the test pads 6.

The single test pad 6 is for accessing the generated N-Well or P-Well bias voltage generated by the first and second adaptive body bias generator 4, 5 from outside of the semiconductor device.

Although FIG. 2 shows an embodiment with two biased logic domains, the invention generally refers to an adaptive body biasing system 1 comprising multiple biased logic domains 3, 4, multiple adaptive body bias generators 4, 5 and multiple bias switch cells 7, 8, wherein each adaptive body bias generator 4, 5 is connected to a corresponding biased logic domain 2, 3, and wherein each adaptive body bias generator 4, 5 is connected to the single test pad 6 via a corresponding bias switch cell 7, 8.

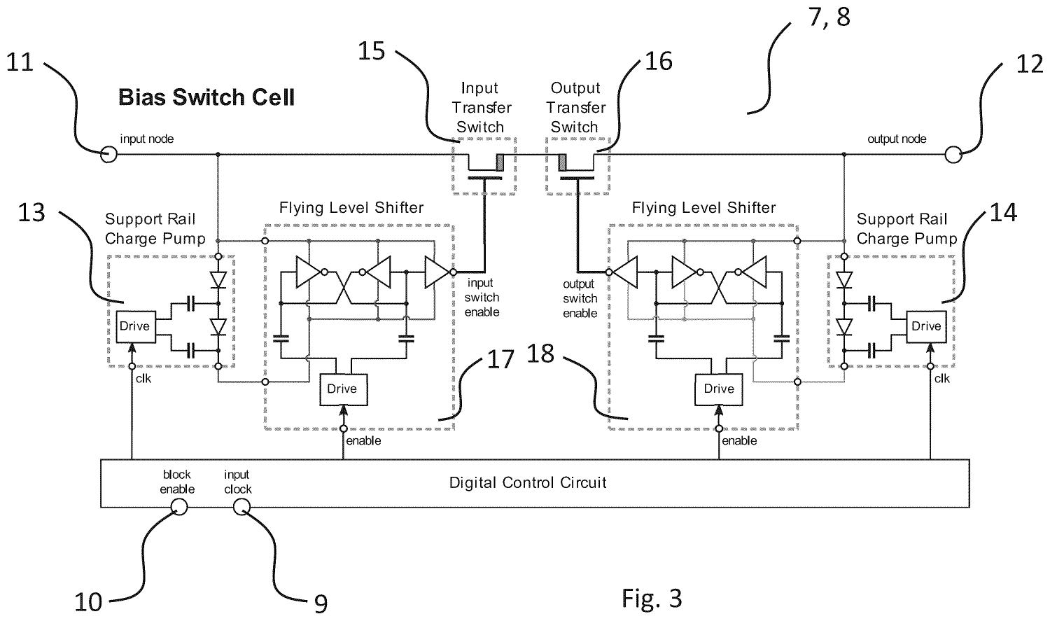

FIG. 3 shows a circuit diagram of a first embodiment of a bidirectional bias switch cell 7, 8 for connecting an input connection node 11 and an output connection node 12. Such a bias switch cell 7, 8 can be for example used in the embodiments of an adaptive body biassing system 1 as shown in FIGS. 1 and 2.

Generally, a bias switch cell 7, 8 provides a configurable high-resistive (open) or low resistive (short) circuit connection between two nodes 11, 12 of arbitrary voltage, especially well bias voltages of high-positive (higher than supply) or low negative (lower than ground) voltage levels.

The bias switch cell 7, 8 shown in FIG. 3 comprises a clock signal input 9 and an enable signal input 10 as control signals. The control signals provided to each bias switch cell 7, 8 are independent and share no reference with the connection nodes 11, 12. Particularly, the dynamic control signal of the switch 7, 8 is independent and shares no reference with the connected nodes 11, 12.

The bias switch cell 7, 8 shown in FIG. 3 comprises a series connection of an input transfer switch 15, 26 and an output transfer switch 16, 27 each having a high voltage rating for the respective input connection node 11, 22 and output connection node 12, 23, which together realize a resistive bidirectional switch element 7, 8 between the input connection node 11, 22 and output connection node 12, 23. The series connection of the input transfer switch 15, 26 and output transfer switch 16, 27 is arranged between the first input connection node 11, 22 and first output connection node 12, 23.

The bias switch cell 7, 8 of FIG. 3 further comprises an input charge pump 13, 24, an output charge pump 14, 25, an input level shifter 17, 28 and an output level shifter 18, 29 for the input transfer switch 15, 26 and output transfer switch 16, 27. Particularly, the input charge pump 13, 24 is connected to the input connection node 11, 22 and the input level shifter 17, 28 and the input level shifter 17, 28 is further connected to the input transfer switch 15, 26. Likewise, the output charge pump 14, 25 is connected to the output connection node 12, 23 and the output level shifter 18, 29 and the output level shifter 18, 29 is further connected to the output transfer switch 16, 27.

Maximum allowed voltage difference of the connected nodes 11, 12, 22, 23 depends on the voltage rating of the driving device with the highest ratings in a given technology, which is usually much higher than for regular devices. Common example for modern technologies: 1V core device rating, 2-3V thick oxide device rating, 5-10V power MOSFET device rating.

When the dynamic components of the bias switch cell 7,8 are disabled, the switch 7, 8 automatically assumes an open-circuit state with high resistance between the connected nodes 11, 12, 22, 23. Therefore, dynamic power consumption of a bias switch cell 7, 8 is only observed for actively shorted nodes.

The internal circuitry of the bias switch cell shown in FIG. 3 includes: a charge pump 13, 14, 24, 25 for each connection node 11, 12, 22, 23 which generates a support voltage with a relative offset from the respective connection node 11, 12, 22, 23: a transfer gate device 15, 16, 26, 27 with high voltage rating for each connection node 11, 12, 23, 24, which together realize a resistive bidirectional switch element 7, 8 between the connection nodes 11, 12, 22, 23: and a level shifter 17, 18, 28, 29 for each connection node 11, 12, 22, 23, which translates a dynamic control signal into an open or close information for the transfer gate device 15, 16, 26, 27.

The level shifter 17, 18, 28, 29 uses a connection node 11, 12, 22, 23 and a support voltage as reference nodes.

Advantageously, the at least bias switch cell 7, 8 is bidirectional. Bidirectional in sense of the present invention means that signals can be transferred from an input connection node 11, 22 to the corresponding output connection node 12, 23 and from an output connection node 12, 23 to the corresponding input connection node 11, 22.

Variants of the bias switch cell 7, 8 for high-positive voltage (e. g. VNW) and low-negative voltage (e. g. VPW) are distinguished by the pumping direction of the support rail charge pump, internal enable and switch polarities, as well as device types that are used in accordance to either positive or negative voltage operation:
i. Support voltage for VNW is pumped above VNW, enable and switch polarities are positive i. e. a gate voltage higher than VNW will close the transfer switch device.
ii. Support voltage for VPW is pumped below VPW, enable and switch polarities are negative i. e. a gate voltage lower than VPW will close the transfer switch device.

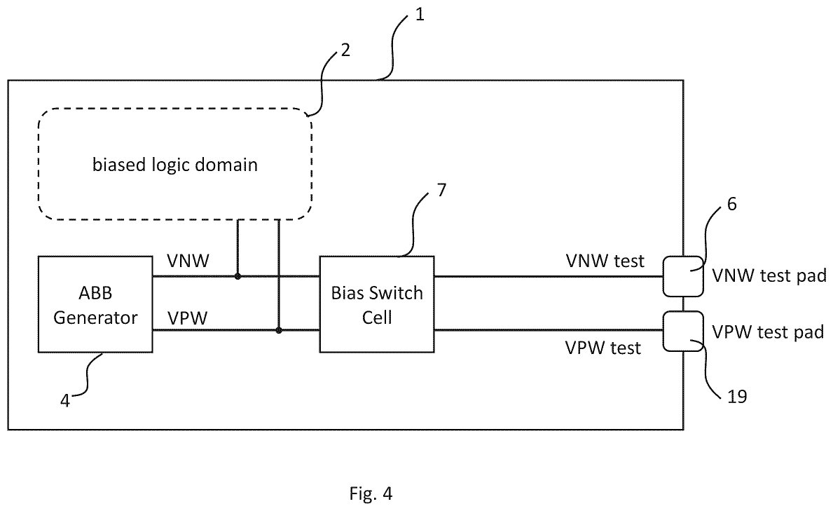

FIG. 4 shows a block diagram of a third embodiment of an adaptive body bias system 1 with a single ABB domain 2, 3 with bias switch cell 7, 8 for test-pad 6, 19 connection. This embodiment differs from the first embodiment shown in FIG. 1 in that the adaptive body bias (ABB) generator 4, 5 generates a variable bias voltage for N-Well biased logic domains and a variable bias voltage for P-Well biased logic domains. The N-Well and P-Well voltages are bother forwarded to the biased logic domain 2, 3 of the adaptive body biasing system 1 shown in FIG. 4.

The adaptive body biasing system 1 shown in FIG. 4 comprises a first test pad 6 for the N-Well bias voltage and a second test pad 19 for the P-Well bias voltage, which are both generated by the ABB generator 4, 5.

The bias switch cell 7, 8 selectively connects the N-Well bias voltage to the firs test pad 6 and the P-Well bias voltage to the second test pad 19 in the low-resistive on state during test operation.

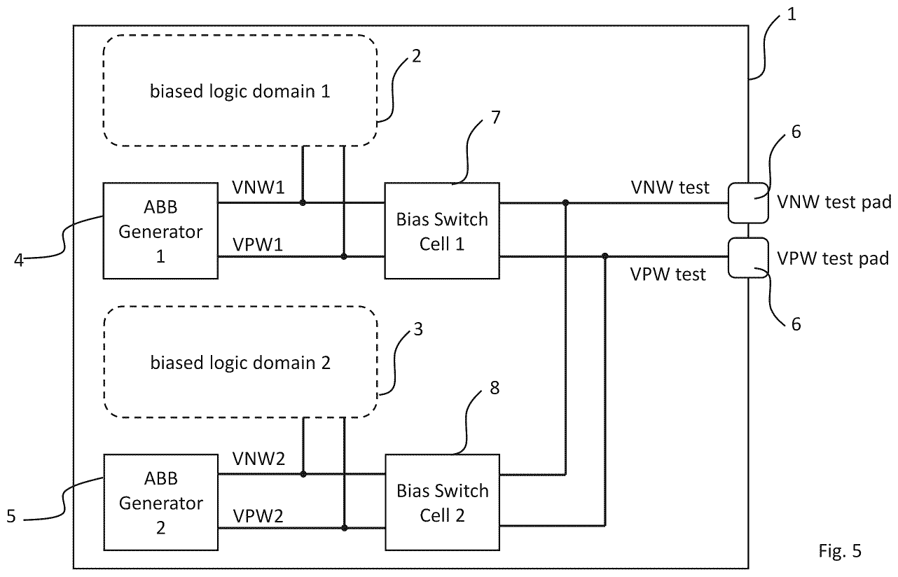

FIG. 5 shows a block diagram of a fourth embodiment of an adaptive body bias system 1 with multiple ABB domains 4, 5 with bias switch cells 7, 8 for test-pad 6, 19 connection. This embodiment differs from the second embodiment shown in FIG. 2 in that the adaptive body bias (ABB) generators 4, 5 each generate a variable bias voltage for N-Well biased logic domains and a variable bias voltage for P-Well biased logic domains. The N-Well and P-Well voltages are both forwarded to the respective biased logic domain 2, 3 of the adaptive body biasing system 1 shown in FIG. 5.

Like in the third embodiment shown in FIG. 4, the adaptive body biasing system 1 shown in FIG. 5 comprises a first test pad 6 for the N-Well bias voltage and a second test pad 19 for the P-Well bias voltage, which are both generated by the ABB generators 4, 5.

The bias switch cells 7, 8 selectively connect the N-Well bias voltage to the first test pad 6 and the P-Well bias voltage to the second test pad 19 in the low-resistive on state during test operation. During test operation, only one of the bias switch cells 7, 8 is in low resistive on state, while the other bias switch cell 7, 8 is in high-resistive off state. Thus, only one bias voltage is connected to a respective test pad 6, 19.

Although FIG. 5 shows an embodiment with two biased logic domains 4, 5, the invention generally refers to an adaptive body biasing system 1 comprising multiple biased logic domains 3, 4, multiple adaptive body bias generators 4, 5 and multiple bias switch cells 7, 8, wherein each adaptive body bias generator 4, 5 is connected to a corresponding biased logic domain 2, 3, and wherein each adaptive body bias generator 4, 5 is connected to the single test pad 6, 19 via a corresponding bias switch cell 7, 8.

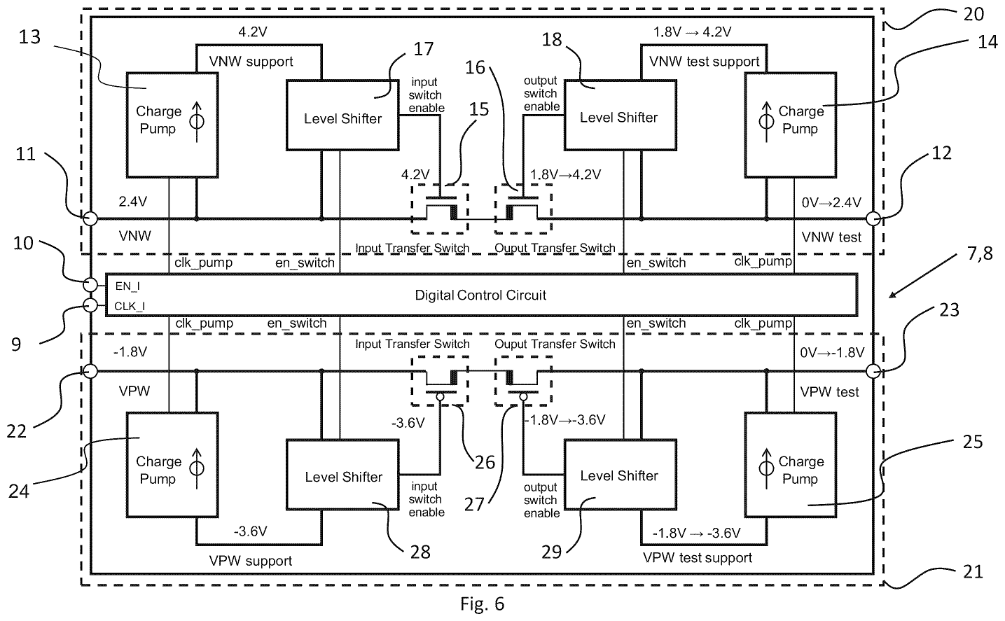

FIG. 6 shows a circuit diagram of a second embodiment of a bidirectional bias switch cell 7, 8 for connecting an input node 11, 22 to an output node 12, 23. Particularly, the bias switch cell 7, 8 can separately forward an N-Well bias voltage and an P-Well bias voltage from an adaptive bias voltage generator 4, 5 to a first test pad 6 for the N-Well bias voltage and a second test pad 19 for the P-Well bias voltage. Such a bias switch cell 7, 8 can be for example used in the embodiments of an adaptive body biassing system 1 as shown in FIGS. 4 and 5.

Generally, a bias switch cell 7, 8 provides a configurable high-resistive (open) or low resistive (short) circuit connection between two nodes 11, 12 of arbitrary voltage, especially well bias voltages of high-positive (higher than supply) or low negative (lower than ground) voltage levels.

The bias switch cell 7, 8 shown in FIG. 6 comprises a first signal path 20 for the N-Well bias voltage generated by the at least one adaptive body bias generator 4, 5 and a second signal path 21 for the P-Well bias voltage generated by the at least one adaptive body bias generator 4, 5.

The first signal path 20 comprises a first input connection node 11, a first output connection node 12, a first input charge pump 13, a first output charge pump 14, a first input transfer switch 15, a first output transfer switch 16, a first input level shifter 17 and a first output level shifter 18. The first input charge pump 13 is connected to the first input connection node 11 and the first input level shifter 17 and the first input level shifter 17 is further connected to the first input transfer switch 15 and the first output charge pump 14 is connected to the first output connection node 12 and the first output level shifter 18 and the first output level shifter 18 is further connected to the first output transfer switch 16.

Likewise, the second signal path 21 comprises a second input connection node 22, a second output connection node 23, a second input charge pump 24, a second output charge pump 25, a second input transfer switch 26, a second output transfer switch 27, a second input level shifter 28 and a second output level shifter 29. The second input charge pump 24 is connected to the second input connection node 22 and the second input level shifter 28 and the second input level shifter 28 is further connected to the second input transfer switch 26 and the second output charge pump 25 is connected to the second output connection node 23 and the second output level shifter 29 and the second output level shifter 29 is further connected to the second output transfer switch 27.

The series connection of the first input transfer switch 15 and first output transfer switch 16 is arranged between the first input connection node 11 and first output connection node 12. The series connection of the second input transfer switch 26 and second transfer switch 27 is arranged between the second input connection node 22 and second output connection node 23.

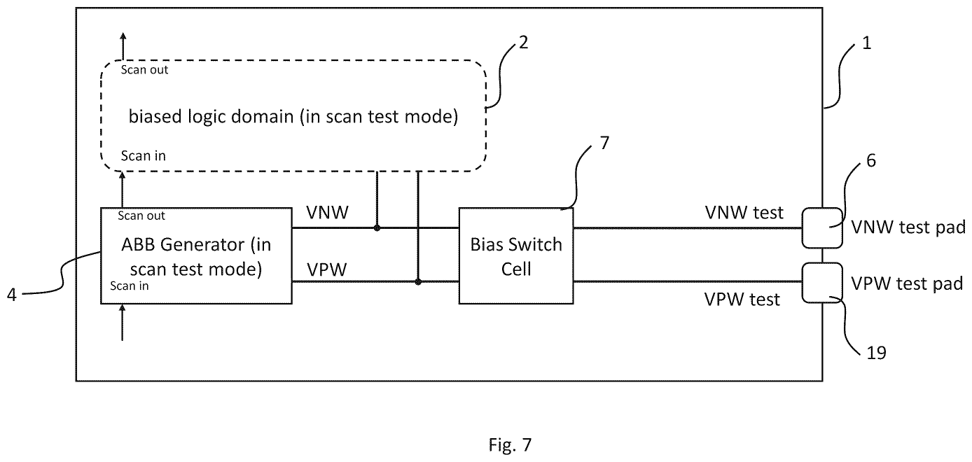

FIG. 7 shows a block diagram of an adaptive body bias system 1 under scan test with ABB generator scan chains and biased logic domain scan chains connected together. For test and debug purposes bias voltages from external sources are applied to the biased logic domains 2. This has the advantage that the body bias generator 4 itself can be in non-functional mode (e. g. scan test) to be tested with the other logic in the biased logic domains 2. The scan chains of the adaptive body bias generator 4 and the biased logic domains 2 are connected together, and the bias is externally supplied. The testing and debugging comprises the steps:
i. Enable selection out of the multiple bias switch cells 7, 8 to connect multiple biased logic domains 2, 3 instance to the test pads 6;
ii. apply bias voltages from external voltage sources;
iii. operate the logic inside the biased logic domains 2, 3 in functional mode or in test mode. This allows connecting the scan chains to the ABB generator scan chain.

1. An adaptive body biasing system for silicon on insulator semiconductor devices, comprising:
at least one biased logic domain;
at least one adaptive body bias generator for generating variable bias voltages for N-Well and/or P-Well biased logic domains, wherein the at least one adaptive body bias generator is connected to the at least one biased logic domain;
at least one test pad for accessing the generated N-Well or P-Well bias voltage generated by the at least one adaptive body bias generator from outside of the semiconductor device; and
at least one bias switch cell connecting the at least one adaptive body bias generator to the at least one test pad and having a high-resistive off state and a low-resistive on state, wherein the at least one bias switch cell is in high-resistive off state during normal operation of the semiconductor device and can be switched to low-resistive on state during test operation.

2. The adaptive body biasing system according to claim 1, comprising multiple biased logic domains, multiple adaptive body bias generators and multiple bias switch cells, wherein each adaptive body bias generator is connected to a corresponding biased logic domain, and wherein each adaptive body bias generator is connected to the at least one test pad via a corresponding bias switch cell.

3. The adaptive body biasing system according to claim 2, wherein during test operation only one of the multiple bias switch cells is in low-resistive on state.

4. The adaptive body biasing system according to claim 1, wherein each bias switch cell comprises a clock signal input and/or enable signal input as a control signal and an input connection node for the at least one adaptive body bias generator and an output connection node for the at least one test pad.

5. The adaptive body biasing system according to claim 4, wherein the control signal provided to each bias switch cell is independent and shares no reference node with the connection nodes.

6. The adaptive body biasing system according to claim 1, wherein the bias switch cell comprises a transfer gate device comprising a series connection of an input transfer switch and an output transfer switch each having a high voltage rating for the respective input connection node and output connection node, which together realize a resistive bidirectional switch element between the connection nodes.

7. The adaptive body biasing system according to claim 6, wherein the at least one bias switch cell comprises an input charge pump, an output charge pump, an input level shifter and an output level shifter for the respective input transfer switch and respective output transfer switch, wherein the input charge pump is connected to the input connection node and the input level shifter and the input level shifter is further connected to the input transfer switch and the output charge pump is connected to the output connection node and the output level shifter and the output level shifter is further connected to the output transfer switch.

8. The adaptive body biasing system according to claim 7, wherein the level shifter uses a connection node and a support voltage as reference nodes.

9. The adaptive body biasing system according to claim 1, wherein the adaptive body biasing system comprises a first test pad for the N-Well bias voltage generated by the at least one adaptive body bias generator and a second test pad for the P-Well bias voltage generated by the at least one adaptive body bias generator.

10. The adaptive body biasing system according to claim 9, wherein the at one switch cell comprises a first signal path for the N-Well bias voltage generated by the at least one adaptive body bias generator and a second signal path for the P-Well bias voltage generated by the at least one adaptive body bias generator.

11. The adaptive body biasing system according to claim 10, wherein the first signal path comprises a first input connection node, a first output connection node, a first input charge pump, a first output charge pump, a first input transfer switch, a first output transfer switch, a first input level shifter and a first output level shifter and the second signal path comprises a second input connection node, a second output connection node, a second input charge pump, a second output charge pump, a second input transfer switch, a second output transfer switch, a second input level shifter and a second output level shifter.

12. The adaptive body biasing system according to claim 1, wherein the at least bias switch cell is bidirectional.

13. The adaptive body biasing system according to claim 12, further comprising a test mode, in which the adaptive body bias generator is in a non-functional mode and a bias voltage is externally applied to the adaptive body biasing system.

14. A production test method for testing single or multiple adaptive body bias generators using an adaptive body biasing system according to claim 1, wherein a measurement of the generated bias voltage comprises the steps of:
enable one bias switch cell to connect a single adaptive body bias generator to the at least one test pad;
enable the selected adaptive body bias generator;
measure the bias voltage at the at least one test pad;
disable the bias switch cell; and
disable the adaptive body bias generator.

15. The method according to claim 14, wherein a measurement of the adaptive body bias generator output current comprises the steps of:
enable one bias switch cell to connect a single adaptive body bias generator to the at least one test pad;
enable the selected adaptive body bias generator; apply a DC voltage source to the at least one test pad;
measure the current flowing through the at least one test pad;
disable the bias switch cell; and
disable the adaptive body bias generator.

16. The method according to claim 14, wherein a testing and debugging comprises the steps of:
enable one or more bias switch cells to connect one or more adaptive body bias generators to the at least one test pad;
apply a bias voltage from external voltage source to the at least one test pad;
operate the logic in the biased logic domains in functional mode or in test mode;
disable the one or more bias switch cells; and
disable the one or more adaptive body bias generators.

17. The method according to claim 15, wherein a testing and debugging comprises the steps of:
enable one or more bias switch cells to connect one or more adaptive body bias generators to the at least one test pad;
apply a bias voltage from external voltage source to the at least one test pad;
operate the logic in the biased logic domains in functional mode or in test mode;
disable the one or more bias switch cells; and
disable the one or more adaptive body bias generators.

18. The adaptive body biasing system according to claim 5, wherein the bias switch cell comprises a transfer gate device comprising a series connection of an input transfer switch and an output transfer switch each having a high voltage rating for the respective input connection node and output connection node, which together realize a resistive bidirectional switch element between the connection nodes.

19. The adaptive body biasing system according to claim 8, wherein the adaptive body biasing system comprises a first test pad for the N-Well bias voltage generated by the at least one adaptive body bias generator and a second test pad for the P-Well bias voltage generated by the at least one adaptive body bias generator.
